(19) United States
(12) Patent Application Publication
(10) Pub. No.: US 2015/0115969 A1
(43) Pub. Date: Apr. 30, 2015

(54) STORAGE BATTERY ANALYSIS SYSTEM, STORAGE BATTERY ANALYSIS METHOD AND STORAGE BATTERY ANALYSIS PROGRAM

(71) Applicants: Takaharu Ishida, Tokyo (JP); Kazumi Rissen, Tokyo (JP); Taminori Tomita, Tokyo (JP); Michiki Nakano, Tokyo (JP); Yasuko Shiga, Tokyo (JP); Hiroki Kurita, Tokyo (JP)

(72) Inventors: Takaharu Ishida, Tokyo (JP); Kazumi Rissen, Tokyo (JP); Taminori Tomita, Tokyo (JP); Michiki Nakano, Tokyo (JP); Yasuko Shiga, Tokyo (JP); Hiroki Kurita, Tokyo (JP)

(73) Assignees: Hitachi Solutions, Ltd., Tokyo (JP); Hitachi, Ltd, Tokyo (JP)

(21) Appl. No.: 14/381,752

(22) PCT Filed: Mar. 2, 2012
(86) PCT No.: PCT/JP2012/055387

§ 371 Date: Oct. 7, 2014

(51) Int. Cl. G01R 31/36

(52) U.S. Cl. CPC G01R 31/3648; G01R 31/361
USPC 324/426

(57) ABSTRACT

A storage battery analysis system includes a storage device storing data of time series variation of a voltage value and a current value during a charging period of a storage battery and data of time series variation of the voltage value and the current value during the charging period of the storage battery; and an arithmetic device that executes a process to read out the time series variation data of the voltage value and the current value during the charging period of the battery, compares the read time series variation data, identifies a difference in the time series variation between the initial usage period and the analysis period, and stores in the storage device the difference as an index indicating a degradation state of the storage battery.

### TECHNICAL FIELD

The present invention relates to a storage battery analysis system, a storage battery analysis method, and a storage battery analysis program.

### BACKGROUND

Various appliances that use a storage battery, such as an electric car, a hybrid car, or a power generating system utilizing regenerative energy, are increasing. On the other hand, the storage battery has a property that its capability degrades with its use frequency or over time. There is proposed a technique that estimates a degradation state of such a storage battery, and to put it to use in managing the storage battery.

For example, there is proposed such as a technique of a life determining device of a storage battery that is used in a car having an idle stop function and which determines that the storage battery is dead in the case that a charging state at the time of starting an engine after the idling stops is equal to or more than a first threshold, and a voltage of the storage battery at that time is equal to or smaller than a first threshold voltage that is a voltage equal to or greater than a minimum voltage for starting an engine (refer to PTL1).

Further, there is also proposed such as a technique (refer to PTL 2) to limit charge and discharge of a storage battery, based on battery property including a maximum value of a charge-discharge current that can be discharged, a maximum value of use temperature of a battery, and a maximum value of a charge-discharge amount that a battery can charge and discharge, at the time a charge-discharge current of the storage battery exceeds the maximum value, or at the time the use temperature exceeds the maximum value.

### CITATION LIST

### Patent Literature

[PTL 1] Japanese Patent Application Laid-open Publication No. 2004-190604
[PTL 2] Japanese Patent Application Laid-open Publication No. 2011-172409

### SUMMARY

### Technical Problem

In conventional techniques there are relatively many cases where a degradation state of a storage battery is estimated based on a SOC (State of Charge) value in which a large error is easily included. In such a case, there is a problem that the reliability of the estimated result regarding the degradation state becomes low, according to an error of the SOC value. Further, in the case that reliability of the estimated result of the degradation state is low, the storage battery is to be used in an operating range of the SOC with a large margin, and there is also a problem from the viewpoint of efficient use of the storage battery. In other words, accurate estimation of the degradation state of the storage battery, and thus efficient use of the storage battery had not been performed.

This invention aims to provide a technique that can accurately estimate a degradation state of a storage battery.

### Solution to Problem

A storage battery analysis system of the present invention comprises:

a storage device storing data of time series variation of a voltage value and a current value during a charging period of a storage battery measured in an initial usage period within a certain period from start of usage, and data of time series variation of the voltage value and the current value during the charging period of the storage battery measured in an analysis period after the certain period has passed; and

an arithmetic device that executes a process to read out the time series variation data of the voltage value and the current value during the charging period of the battery measured in the initial usage period and the time series variation data of the voltage value and the current value during the charging period of the battery measured in the analysis period, compare the respective time series variation data as read, identify a difference in the time series variation between the initial usage period and the analysis period, and store in the storage device the difference as an index indicating a degradation state of the storage battery.

A storage battery analysis method of this invention, the method comprises

causing a computer having a storage device storing data of time series variation of a voltage value and a current value during a charging period of a storage battery measured in an initial usage period within a certain period from start of usage, and data of time series variation of the voltage value and the current value during the charging period of the storage battery measured in an analysis period after the certain period has passed,

to execute a process to read out from the storage device the time series variation data of the voltage value and the current value during the charging period of the battery measured in the initial usage period and the time series variation data of the voltage value and the current value during the charging period of the battery measured in the analysis period, compare the respective time series variation data as read, identify a difference in the time series variation between the initial usage period and the analysis period, and store in the storage device the difference as an index indicating a degradation state of the storage battery.

A storage battery analysis program of this invention, the program comprises

causing a computer having a storage device storing data of time series variation of a voltage value and a current value during a charging period of a storage battery measured in an initial usage period within a certain period from start of usage, and data of time series variation of the voltage value and the current value during the charging period of the storage battery measured in an analysis period after the certain period has passed,

to execute a process to read out from the storage device the time series variation data of the voltage value and the current value during the charging period of the battery measured in the initial usage period and the time series variation data of the voltage value and the current value during the charging period of the battery measured in the analysis period, compare the respective time series variation data as read, identify a difference in the time series variation between the initial usage period and the analysis period, and store in the storage device the difference as an index indicating a degradation state of the storage battery.

### Advantageous Effects of Invention

According to this invention, the degradation state of the storage battery can be accurately estimated.

### BRIEF DESCRIPTION OF DRAWINGS

FIG. 1 shows a configuration example of a storage battery analysis system in the present embodiment.

FIG. 2 shows a graph of certain stored data of a storage battery model DB of this embodiment.

FIG. 3 shows a time series variation example of a voltage and a current in CC-CV charging.

FIG. 4 shows a time series variation example of a voltage and a current in CC-CV charging.

FIG. 5 shows a time series variation example of a voltage and a current in CC charging.

FIG. 6 is a flow chart showing a process procedural example of a storage battery analysis method in this embodiment.

FIG. 7 shows an example of charging data in this embodiment.

FIG. 8 shows a configuration example of a charging planning system using a storage battery analysis system in this embodiment.

FIG. 9 shows a configuration example of a power demand amount predicting device in this embodiment.

FIG. 10 shows a configuration example of a power supply amount predicting device in this embodiment.

FIG. 11 shows a configuration example of a demand and supply planning control device in this embodiment.

FIG. 12 shows a supplemental example regarding a degradation state based on an index of storage battery degradation in this embodiment.

### DESCRIPTION OF EMBODIMENTS

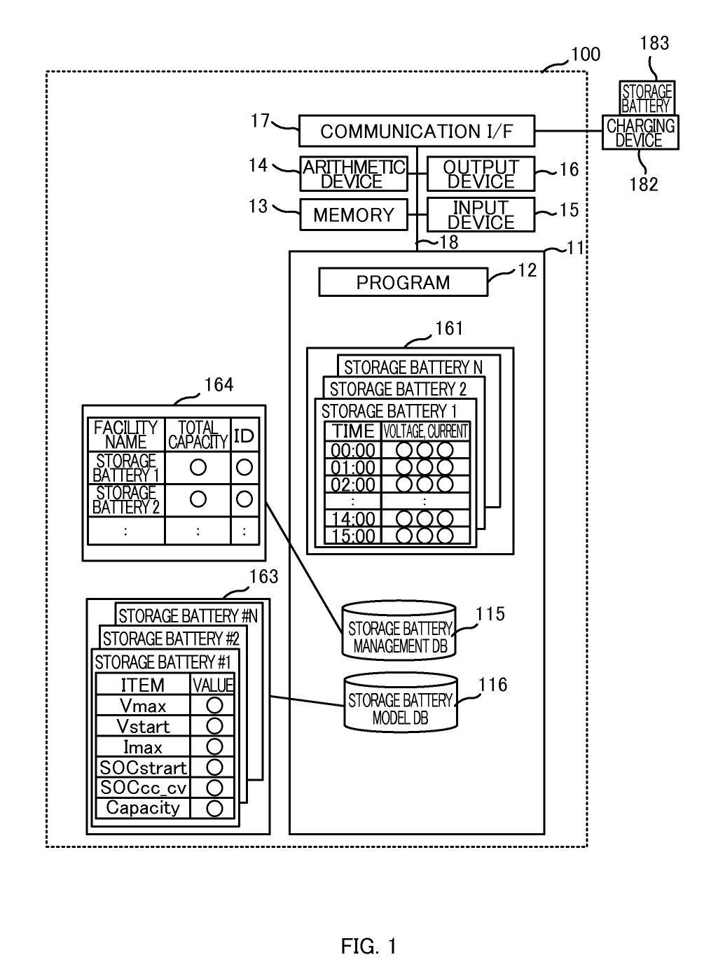

Hereafter, an embodiment of the present invention will be described in detail with reference to the drawings. FIG. 1 shows a configuration example of a storage battery analysis system in this embodiment. A storage battery analysis system 100 shown in FIG. 1 is a computer system for accurately estimating a degradation state of a storage battery. A hardware configuration of the storage battery analysis system 100 in this embodiment is as shown below. The storage battery analysis system 100 includes a storage device 11 configured with an appropriate non-volatile storage device such as a hard disk drive, a memory 13 configured with a volatile storage device such as RAM, an arithmetic device 14 such as a CPU that reads out a program 12 held in the storage device 11 to a memory 103 and executes the program and performs overall control of the system itself and also performs various determinations, arithmetic and control processes, an input device 15 that receives key inputs or a voice input from a user, an output device 16 such as a display that displays process data, and a communication I/F 17 that connects with a network and carries out communication process with other devices. Further, the above devices are connected via a communication bus 18.

Note that, the storage device 11 stores at least a program 12, a storage battery management DB 115, and a storage battery model DB 116 to implement a function necessary as the storage battery analysis system in this embodiment. Such a storage battery analysis system 100 performs a degradation diagnosis of a storage battery 183 which is the subject, based on time series variation data of a voltage value and a current value measured with a charging device 182 which is a charging device or a charging station to charge power to the storage battery 183.

Functions of the storage battery analysis system 100 in this embodiment will be described. As described above, the function described hereafter can be said to be a function that is implemented by, for example, executing the program 12 in the storage battery analysis system 100.

In this case, the storage battery analysis system 100 has a function of reading out from the storage device 11 time series variation data (stored data of the storage battery model DB 116) of a voltage value and a current value during a charging period measured in an initial usage period (namely a period in which degradation has not progressed) of the storage battery 183, and time series variation data of a voltage value and a current value during the charging period measured in an analysis period (time series variation data 161 of the voltage value and the current value in last charging and charging that is currently in progress acquired from the charging device 182), compares the read time series variation data, specifies a difference in the time series variation between the initial usage period and the analysis period, and stores information of the difference as an index showing a degradation state of the storage battery 183. A process to acquire the index by identifying the difference will be described in detail later on.

Note that, the index acquired by the storage battery analysis system 100 will be stored in the storage battery management DB 115. This storage battery management DB 115 is a database that manages data of the degradation state of the storage battery 183, and is an aggregate of records that associates a total capacity of the storage battery which is an index showing the degradation state of each storage battery and an ID number allotted to each data retrieval (or each charging). Here the total capacity which is an index showing the degradation state of the storage battery 183 is a total power amount stored during the charging period in the analysis period, acquired regarding the storage battery 183. This amount is less than the total power amount stored during the charging period immediately after start of use.

Further, the storage battery analysis system 100 has functions to communicate with the charging device 182 via the communication I/F 17, acquire time series variation data of the voltage value and the current value during the charging period of the storage battery 183, and store the acquired data 161 in the storage device 11 or the memory 13. The data 161 illustrated in FIG. 1 includes, for each storage battery 183, at least each value of the voltage and the current for each time in the charging period. Note that, the storage battery analysis system 100 may acquire the SOC value with a controller of the storage battery 183 and add it to the data 161.

Further, the storage battery analysis system 100 has a function to decide a type of the storage battery 183 connected to the charging device 182. With this function, the system compares such as a physical amount acquired from the charging device 182 (data regarding voltage and current) and the SOC value to a data table 163 in the storage battery model DB 116, and determines which type of storage battery the storage battery 183 charging with the charging device 182 is. Thus, the storage battery model DB 116 stores data of feature amount of voltage, current, and SOC for each type of storage battery. Further, the storage battery analysis system 100 naturally includes a function to acquire the above physical amount data and the SOC value and the like from the charging device 182 that charges the storage battery 183.

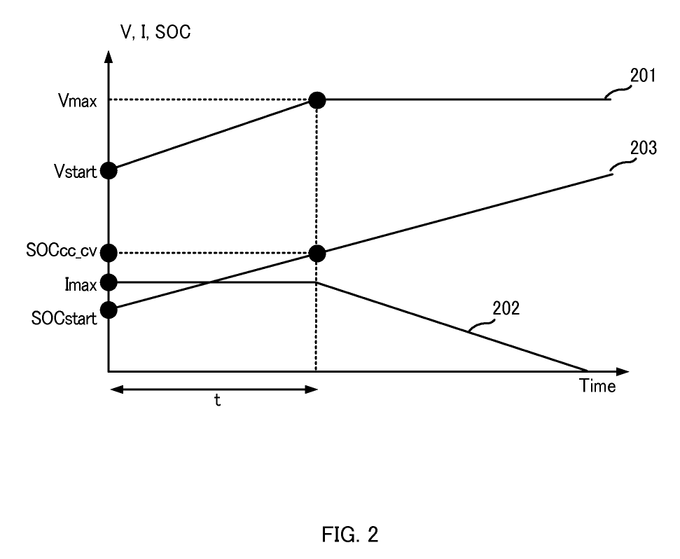

Data accumulated in the storage battery model DB 116 will be described using FIG. 2. FIG. 2 is a graph of certain stored data of the storage battery model DB 116 in this embodiment. In general, when charging the storage battery 183, especially a lithium ion battery, charging is performed with a method called CC (Constant Current) charging that makes the current constant in an initial period of charging, and changes the voltage, and after a certain constant amount of charging has been performed charging is performed with a method called CV (Constant Voltage) charging. Such a schematic drawing is shown in FIG. 2. In the graph in FIG. 2, a horizontal axis shows a time axis, a vertical axis shows the voltage value, the current value and the SOC value. Further, a line segment 201 shows a voltage transition when performing CC charging and CV charging, and the line segment 202 shows a transition of the current when performing the CC charging, CV charging. Note that, a line segment 203 shows a SOC transition. In the case that such charging is performed, as feature amounts, Vmax is a maximum value of voltage, Vstart is a voltage at the time of starting charging, SOCcc_cv which is a SOC value at the time of switching the CC charging and the CV charging, Imax is a maximum value of the current, and SOCstart is a SOC value at the time of starting charging, Further, as a value to show the feature amount of the storage battery 183, the capacity of the storage battery 183 may be used.

The storage battery analysis system 100 extracts and calculates the above feature amounts from the time series variation data of the physical amount and the like acquired for each charging of each storage battery 183, and records a value corresponding to each feature amount type in a table format as the data 163 in the figure. The symbol t showing the CC charging time can be considered as another feature amount, thus this data can also be added to the data 163.

Next, there will be described a process of degradation diagnosis in which the storage battery analysis system 100 acquires the index showing the degradation state of the storage battery 183. Here, in order to acquire the index, data of the voltage value and the current value will be used. The voltage value and the current value are physical amounts with little measurement errors, so that when such accurate data is used the degradation diagnosis of the storage battery 183 can be performed with satisfactory accuracy.

Note that, a duration time of the CC charging which is important in the degradation diagnosis of the storage battery 183 is defined as a time that the current value begins to decrease and the voltage value becomes constant, based on the time series variation data of the voltage value and the current value. Further, at least three types of methods of charging can be considered which are (1) a method of deciding an end of CC charging based on SOC of the storage battery 183, (2) a method of deciding the end of CC charging based on an absolute value of power (kWh) stored in the storage battery 183, and (3) a method of not performing CV charging.

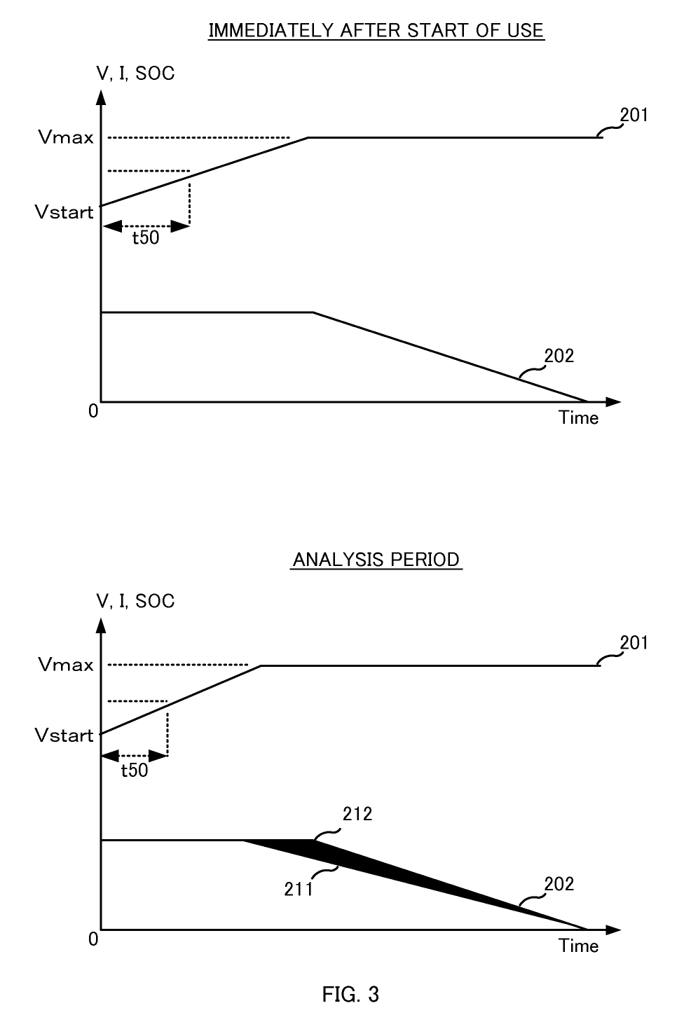

Hereafter, methods to perform degradation diagnosis for each type of the charging methods of above (1) to (3) are described. FIG. 3 is a diagram showing a time series variation example of a voltage and a current in CC-CV charging, specifically FIG. 3 describes the degradation diagnosis method corresponding to the above charging method (1). The top graph in FIG. 3 schematically shows a tendency during the charging period of the battery once of the voltage 201 and the current 202 immediately after starting use of the storage battery 183 (namely, before degradation starts), and is data stored in the storage battery model DB 116. The bottom graph in FIG. 3 is a graph of data acquired regarding a same type of storage battery as the storage battery 183 shown in the top graph (for example, a voltage in an initial period at the time of starting charging is similar), and shows time series variation of the voltage 201 and the current 211 in the case that charging is performed in a period where a certain amount of time has passed from the start of use of the storage battery 183 (analysis period). A blackened region 212 in the bottom graph is an index showing degradation of the storage battery 183.

In the case of the above-described charging method (1), the CC charging and the CV charging are switched using a predetermined SOC value, thus in the case that a storage capacity lessens with the degradation progress of the storage battery 183, the time of the CC charging will naturally lessen. Thus, due to at least the time difference in the CC charging, the region 212 in the bottom graph in FIG. 3, namely a charging power amount corresponding to the region 212 will decrease. In other words, here the power amount corresponding to the region 212 can be acquired as the index. The power amount corresponding to the region 212 can be acquired by multiplying the data of the voltage value and the current value with the voltage and the current in a sampled period.

From such an index, at the time of specifically estimating the degradation state of the storage battery 183, a ratio of a charging total power amount in the top graph in FIG. 3 and a power amount corresponding to the region 212 in the bottom graph are acquired, and this ratio maybe identified as a value showing the degradation state of the storage battery 183. In the above example, the degradation state of the storage battery 183 was evaluated with an area ratio of the region showing the charging power amount in the graph, but other evaluation methods can also be adopted. For example, a technique can be adopted to acquire a ratio of a CC charging time between immediately after starting use and an analysis period as the degradation state. Alternatively, a technique can be adopted in which a ratio of a time t50 in which a value of the voltage 201 from Vstart to 50% of Vmax is acquired as the degradation state. In any case, the degradation state can be estimated from the time series variation data of the voltage and the current shown in FIG. 3.

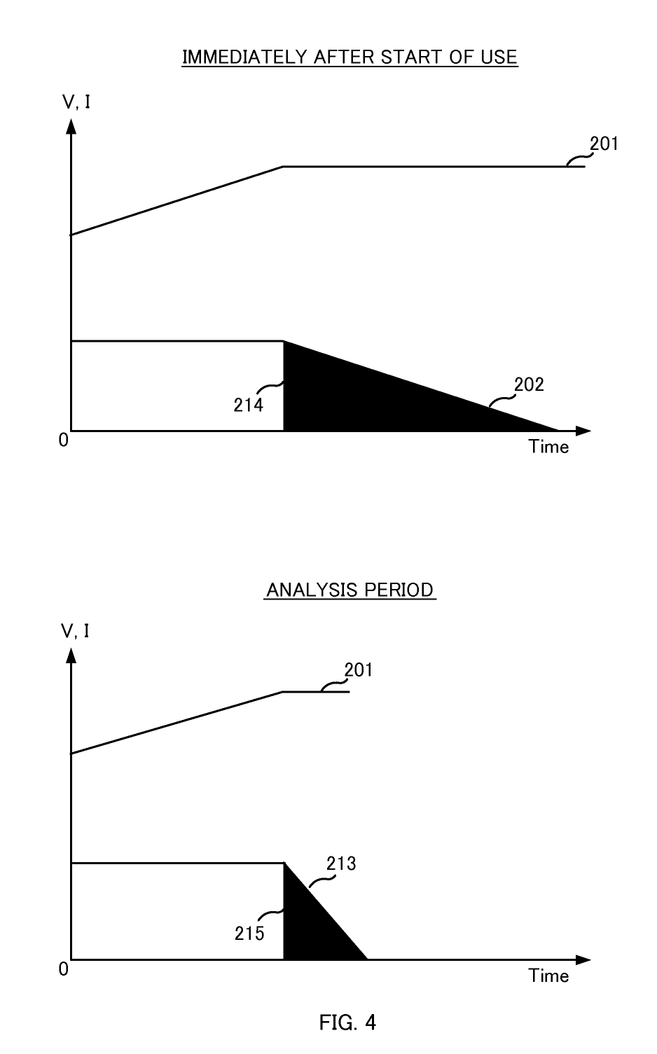

FIG. 4 is diagram showing the time series variation example of the voltage and the current in CC-CV charging, specifically this diagram describes the degradation diagnosis method corresponding to the charging method (2). The top graph in FIG. 4 schematically shows a tendency during one charging period of the voltage 201 and the current 202 immediately after starting use of the storage battery 183. The bottom graph in FIG. 4 is a graph of data acquired regarding the same type of storage battery (for example, voltage in an initial period at the start of charging is similar) as the storage battery 183 shown in the top graph, and shows the time series variation of the voltage 201 and the current 213 in the case of charging in a period in which a certain amount of time has passed since the start of use of the storage battery 183 (analysis period). Further a blackened region 214 in the top graph and a blackened region 215 in the bottom graph are indexes showing the degradation state of the storage battery 183.

In the charging method (2) described above, when charging of a power amount (kWh) decided in advance for each storage battery 183 ends, the process shifts to CV charging. As in the bottom graph, in the case of the storage battery 183 that has progressed in degradation, the storage capacity (absolute value) of the storage battery 183 is small compared to immediately after start of use, thus the charging amount in CV charging decreases. Based on such an understanding, by comparing the power amount corresponding to the region 214 (an integral of the power and the current at the time of sampling) and the power amount corresponding to the region 215, the degradation state of the storage battery 183 can be estimated.

Of course, a technique can be adopted that acquires as the degradation state a ratio of the time until the CV charging ends, between immediately after starting of use and the analysis period. Further, as described regarding the charging method (1), a technique can be adopted to acquire as the degradation state a ratio of a time in which a value of the voltage 201 from Vstart reaches 50% of Vmax, between immediately after start of use and an analysis period.

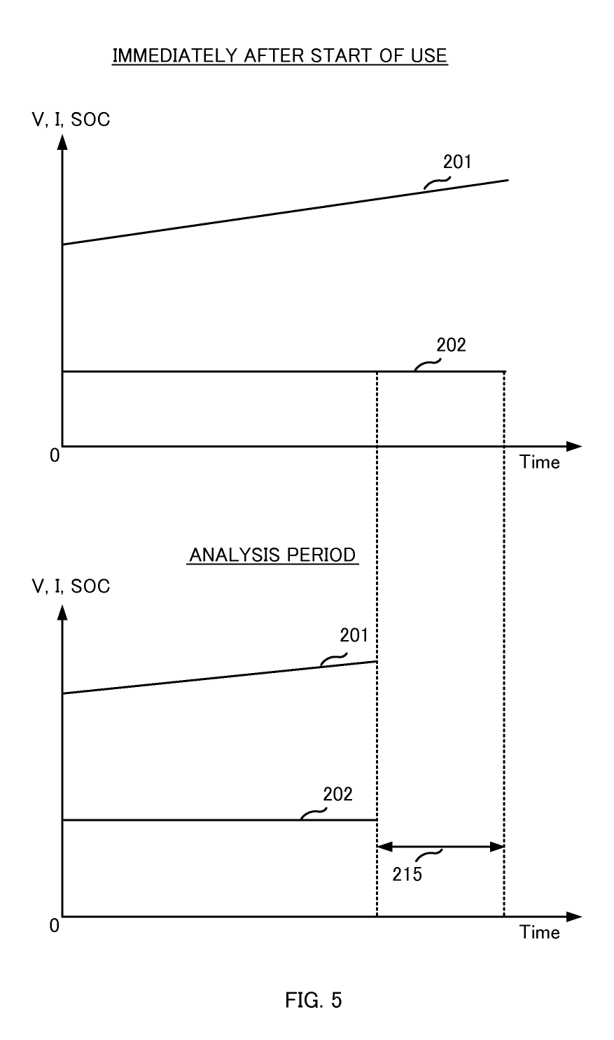

FIG. 5 is a diagram showing the time series variation example of the voltage and the current in CC charging, specifically this diagram describes a degradation diagnosis method corresponding to the charging method (3). The top graph in FIG. 5 schematically shows a tendency during the one charging period of the voltage 201 and the current 202 immediately after starting use of the storage battery 183. The bottom graph in FIG. 5 is a graph of data acquired regarding the same type of storage battery (for example, voltage in an initial period at the start of charging is similar) as the storage battery 183 shown in the top graph, and shows the time series variation of the voltage 201 and the current 202 in the case of performing charging in a period in which a certain amount of time has passed since the start of use of the storage battery 183 (analysis period). In the charging method (3), the storage battery 183 is charged with only the CC-charging, and from the viewpoint of safety of the storage battery, the CC-charging is ended with the predetermined SOC value as a standard. This is because, in the case that the CC-charging is to end with the power amount (absolute value) charged to the storage battery 183 as the standard, there is a possibility that charging will be performed that is equal to or more than the storage capacity that has decreased from the initial time due to the degradation progress. In such a charging method, in the case of charging the storage battery 183 in which degradation has progressed, a time necessary for the CC charging becomes shorter similar to that in the charging method (1). Thus, a difference 215 in time required for the CC charging, between immediately after starting use and the analysis period, is the index, and the degradation state of the storage battery 183 can be estimated.

Hereafter, the actual procedure of the storage battery analysis method in this embodiment is described based on the drawings. Various actions corresponding to the storage battery analysis method described below is realized by a program that is read out by the storage battery analysis system 100 to such as a memory and executed. This program is configured by a code to perform various actions described below.

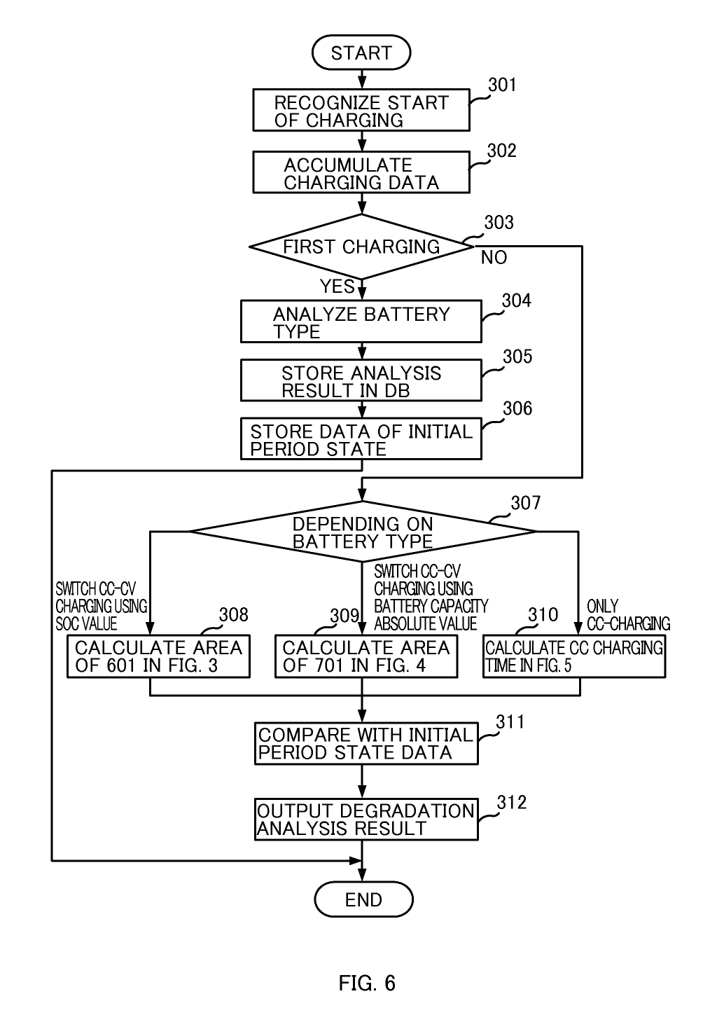

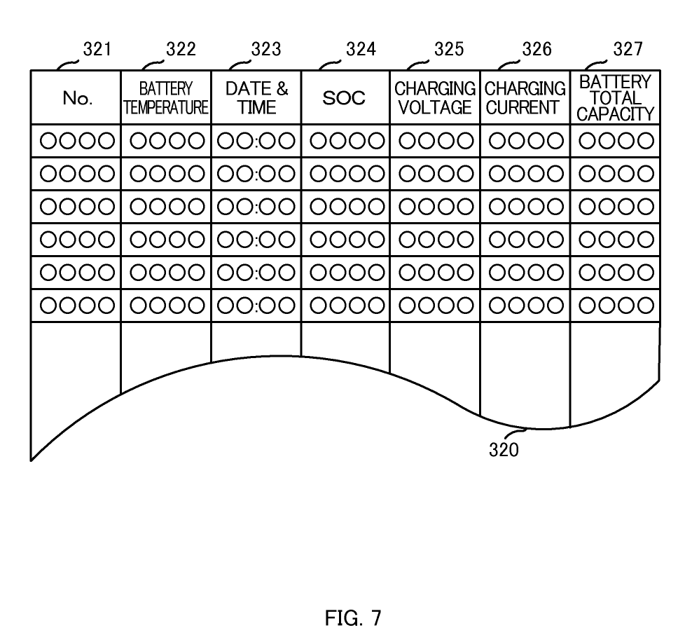

FIG. 6 is a flow chart showing a process procedural example of the storage battery analysis method in this embodiment. In this case, the storage battery analysis system 100 communicates with the charging device 182, acquires data showing that charging has started in respect to the storage battery 183, and recognizes the start of charging (step 301). Then, the storage battery analysis system 100 receives various charging data such as the voltage value and the current value acquired with the charging device 182 during the charging period via the communication I/F 17, and accumulates it in the memory 13 following a format illustrated in FIG. 7 (step 302). The charging data accumulated in the memory 13 (refer to FIG. 7) is a data table 320 including data of ID assigned for each one charging (321), battery temperature (322), data acquiring date and time (323), SOC value when acquiring data (324), charging voltage (325), charging current (326), battery total capacity (327).

Subsequently, the storage battery analysis system 100 determines whether the charging data acquired with the charging device 182 relates to the first charging by inquiring the storage battery management DB 115 (step 303). In this determining, in the case that the charging data relates to a first charging, namely there is no record relating to the storage battery in the storage battery management DB 115 in the past, or there is a record but a predetermined item (for example, a total capacity) is blank, the type of the battery is analyzed (step 304). In this analysis, the charging data regarding each feature amount (such as Vmax, Vstart, Imax, . . . ) stored in the storage battery model DB 116 is checked to determine which charging method of the charging methods shown in FIG. 3 to FIG. 5 the charging data corresponds to. Note that, it is assumed that the charging method is decided in advance for every storage battery type.

When this process ends, the storage battery analysis system 100 stores the analysis result regarding the type of the storage battery in a format of the data table 163 in the storage battery model DB 116 (Step 305). In this situation this is charging data of a first time, and data for determining the degradation of the storage battery is not complete, thus the data of this first period state is stored according to the format of a data table 164 in the storage battery management DB 115 and the whole process ends (Step 306).

On the other hand, in the case that in deciding in the above step 303 it is decided that it is not charging data of a first charging (Step 303:No), the storage battery analysis system 100 compares the relevant charging data with the data table 163 in the storage battery model DB 116, and decides to which charging method (1) to (3) described above, namely the storage battery type, the data corresponds to (Step 307). Here, in the case that the storage battery 183 is, for example, a storage battery that has a pattern of switching CC charging and CV charging using a SOC value, the estimating method used in the explanation in FIG. 3 is used to evaluate the degradation state of the storage battery (Step 308). On the other hand, in the case that in step 307 the storage battery is a storage battery that has a pattern of switching the CC charging and the CV charging using an absolute value of the charging power amount, the estimating method used in the explanation in FIG. 4 is used to evaluate the degradation state of the storage battery (Step 309). Further, in step 307, in the case that charging of the storage battery is to be performed with only the CC charging, the estimating method used in the explanation in FIG. 5 is used to evaluate the degradation state of the storage battery (Step 310).

Next, the storage battery analysis system 100 compares an index regarding degradation of the storage battery accumulated in the past in the table 164 and an index regarding degradation of the storage battery calculated in this process (Step 311), and in the case that both of the indexes are different, namely that the level of degradation has increased, determines that upgrading of the indexes is necessary and updates the content of the table 164 with the indexes acquired in this process, and further outputs the increase of the degradation level (Step 312), and ends the whole process.

In addition to the above embodiment, a system to perform a charge-discharge plan to be established for a charging facility of the storage battery using the storage battery analysis system 100 can also be assumed. For example, when a charging plan is planned with the battery having no degradation, although degradation of the storage battery subject to charging-discharging is progressing, a surplus power in the planned charging power is generated, and an unexpected voltage rise in the power system, in particular the wiring system to which the storage battery is connected, is generated. Further, in the case of a discharging plan from a storage battery, unless degradation of the storage battery is considered, deficiency in a scheduled discharge power occurs, and power deficiency occurs in the power system, in particular the wiring system to which the storage battery is connected, and unexpected voltage drop occurs. This is not a big issue in the case where charging of a few storage batteries is assumed, but for example, in the case where a charging plan is assumed in a format of performing charge-discharge by regarding multiple dispersed storage batteries as one generating station, called a virtual power plant, whether or not the degradation state of each of the storage batteries is considered will have a large influence on the index relating to power quality in the power system and the regional power supply system to which the storage batteries are connected.

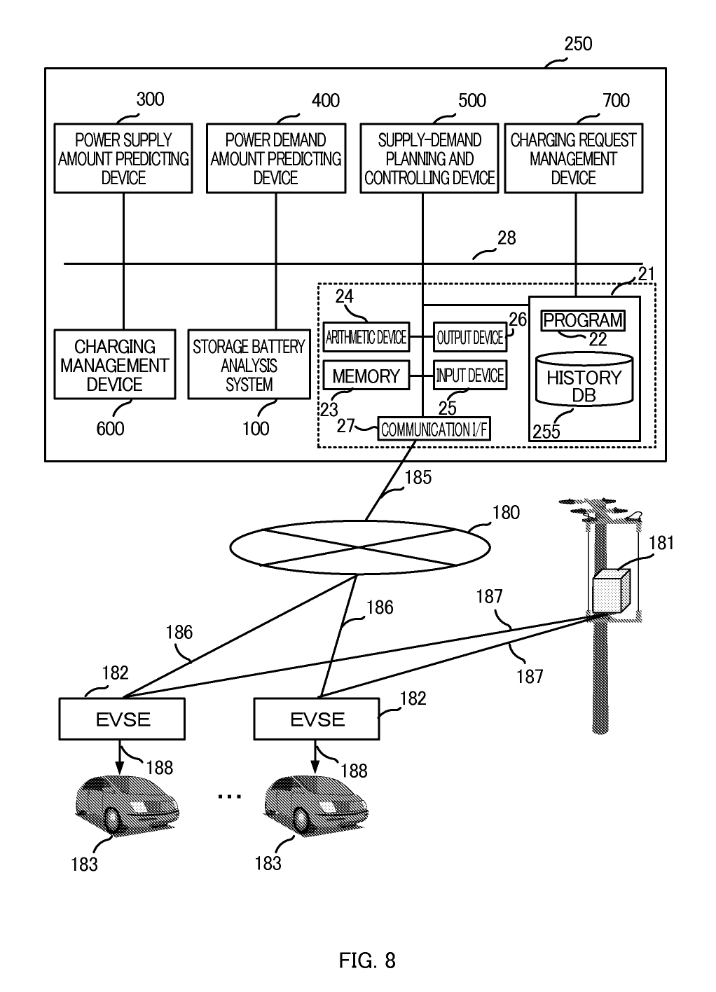

Thus, FIG. 8 shows an embodiment of a charging plan planning system 250 to reduce influence to the index relating to voltage quality to such a power system and regional power supply system. FIG. 8 is a diagram showing a configuration example of the charging plan system 250 using the storage battery analysis system 100 in this embodiment. Note that, the below explanation describes the case of charging for the sake of convenience, and the explanation of the case of discharging can be described by inverting reference codes of the charging power and is thus omitted in this explanation. Further, when considering the charging control system, a time period used in the charging plan planning system 250 (for example, a few hours, a few days) is made as a control period in real time (for example, one minute, a few minutes) so that it can be realized. Further, the process flow of the charging plan planning system can be used as it is, thus explanation thereof is omitted.

The charging plan planning system 250 may include a charging device (EVSE, Electric Vehicle Supply Equipment) 182, a communication network 180 to connect the charging plan planning device 250 and the charging device 182, communication lines 185, 186 which connect the charging plan planning device 250 and the communication network 180, the storage battery 183, a wiring line 187 that gives and receives power from a wiring system, a charging cable 188 to connect the charging device 182 and the storage battery 183, and a pole transformer 181 that steps down power from a basic system and transforms it into an appropriate voltage to the charging device 182. Note that, in the below explanation, the storage battery 183 is assumed to be an electric car for the sake of convenience of explanation. Further, the charging plan planning system 250 may plan a charging plan with a storage battery set to a system side as the subject. In this situation, the storage battery installed to the system side is also the object of the degradation diagnosis.

As shown in FIG. 8, the charging plan planning device 250 is configured from a power supply amount predicting device 300 that predicts a power supply amount of a period of planning a plan, a power demand amount predicting device 400 that predicts a power demand amount in a regional system in a period of planning a plan, a charging planning and controlling device 500 that plans a supply-demand plan or decides a command value of control in respect to the charging device 182, a charging management device 600 that commands the storage battery 183 via the communication I/F 27 a set value of charging to each storage battery 183, a storage battery analysis system 100, the communication I/F 27 that gives and receives data with the charging device 182, a charging request management device 700 that manages a charging request from the electric car 183, a history DB 255 that accumulates data such as power supply amount prediction, power demand amount prediction, and charging demand, and a communication bus 28 that connects the devices 300 to 700. Of course, it is needless to say that the charging plan planning device 250 has an arithmetic device 24, a memory 23, an input device 25, an output device 26, and a storage device 21 that stores a history DB 255 and a program 22 (similar to each device 300 to 700) for calculation. Note that, the content of the history DB 255 includes the contents of data 266-268, 256-258, 276-278, 359, 369, and 379 described later on.

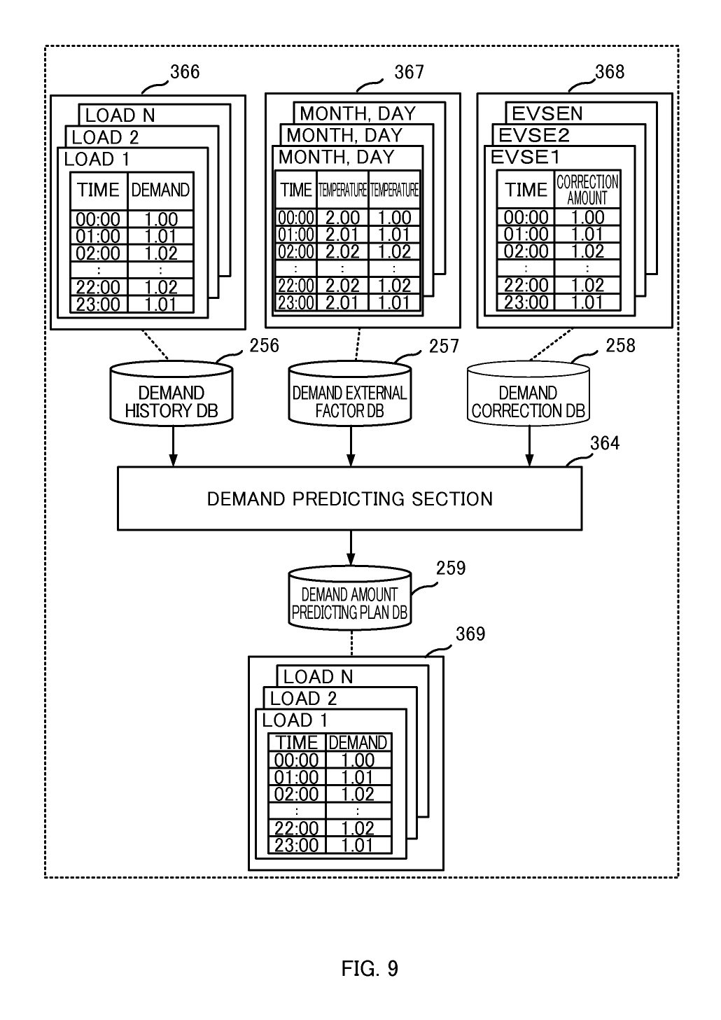

An example of the power demand amount predicting device 400 in the charging plan planning device 250 is shown in FIG. 9. This device predicts the power demand amount including power to charge the storage battery 183, and reflects that result to the power supply amount predicting device 300. The power demand amount predicting device 400 is configured from a demand history DB 256, a demand external factor

DB 257, a demand correction DB 258, a demand predicting section 364, and a demand amount predicting plan DB 259. Data 366 in the demand history DB 256 records time and a power demand amount that agrees with such time, for each load. Further, the demand external factor DB stores factor data 367 that influences power demand, such as a highest temperature, a lowest temperature, humidity, solar radiation amount, and event, for every hour and every day in the past. Further, the demand correction DB 258 stores for every EVSE data regarding a charging request from the electric car 183, which is a storage battery, as a correction amount in the format of data 368.

Further, with data shown in each of the DB 256-258 as inputs, the demand predicting section 364 performs demand amount predicting using techniques represented by an optimization computing technique, for example, a well-known Lagrange's undetermined coefficient method, a regression analysis method, a linear computation method, a neural network, and a Tabu search. Such a result is stored in a demand amount predicting plan DB. In regards to an implementing example of the demand predicting section 364 here, detailed techniques are disclosed in, for example Japanese Patent Application Laid-open Publication No. 4-372046 as an example using a neural network, and for example Japanese Patent Application Laid-open Publication No. 5-38051 as an example using regression analysis. The stored predicted result is stored as the demand amount in response to time for every load, or every EVSE, as shown in the data 369.

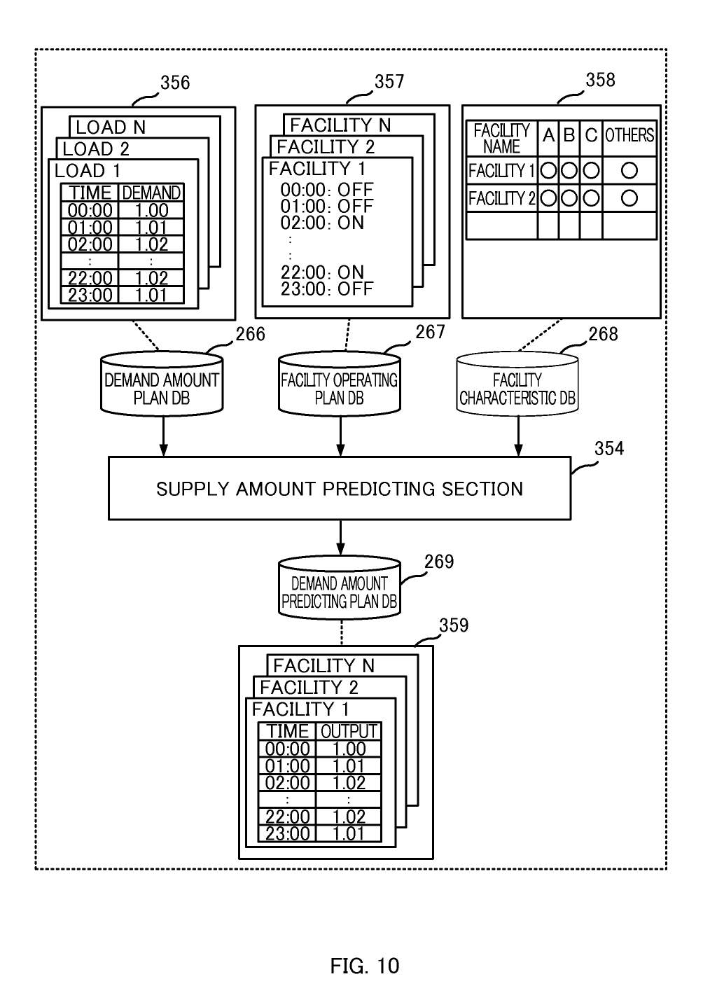

FIG. 10 shows a configuration of the power supply amount predicting device 300 in the charging plan planning device 250. This power supply amount predicting device 300 is configured with a demand amount plan DB 266, a facility operating plan DB 267, a facility characteristic DB 268, a supply amount predicting section 354, and a supply amount predicting plan DB 269. The contents of the demand amount plan DB 266 is the same as the contents of the demand amount predicting plan DB 259 described in the explanation of FIG. 9. Further, an example of a format of the facility operating plan DB 267 is shown in data 357. The data format in the facility operating plan DB 267 is accumulated with information of operating state (ON/OFF) for each time, in respect to each facility. Further, an example of the data format in the facility property DB 268 is shown in data 358. Data in the facility characteristic DB 268 stores parameters regarding operation of each of the facilities, and for example, coefficients (a-c) which are parameters of fuel consumption property of a small generator are stored. The data of this facility characteristic DB 268 is used at the time of deciding a plan output value for every generator in calculation of the supply amount predicting section 354.

Further, with data shown in each of the DB 266-268 as inputs, the supply amount predicting section 354, calculates assuming planning value of the power supply amount using techniques represented by an optimization computing technique, for example, a well-known Lagrange's undetermined coefficient method, a regression analysis method, a linear computation method, a neural network, and a Tabu search. In regards to the implementing example of the supply amount predicting section 354, a detailed technique is disclosed in Japanese Patent Application Laid-open Publication No. 2011-188590 as an example using, for example the linear computation method. This predicting result is stored in the supply amount predicting plan DB 269. The data format of the prediction result, as shown in data 359, records a time and an output amount in response to the time of the power supply facility for every facility.

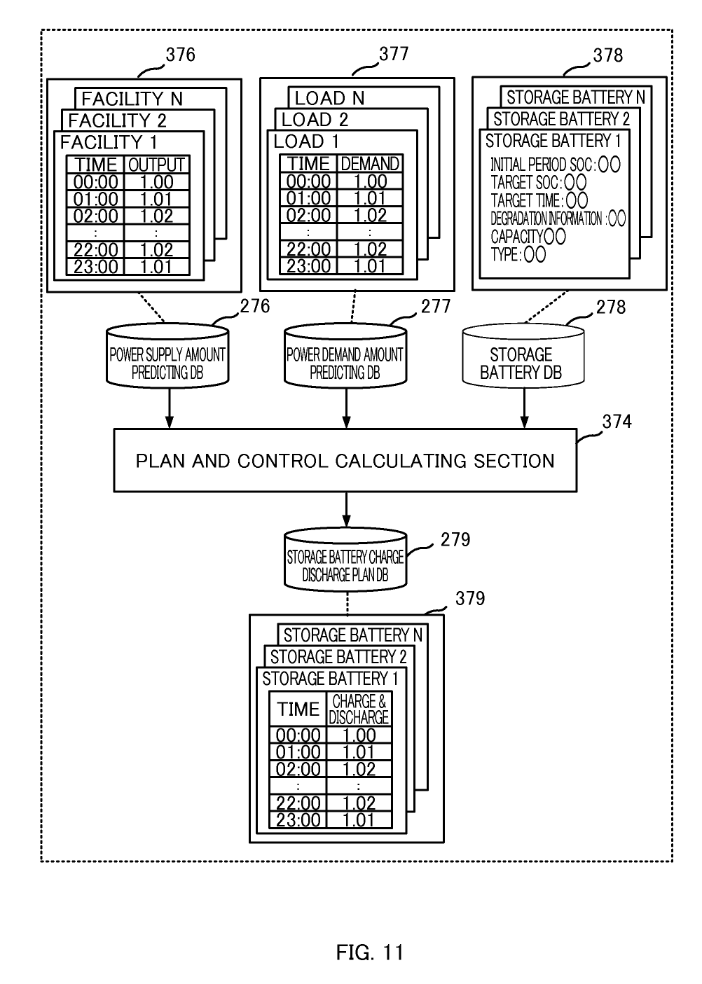

FIG. 11 shows an embodiment of the supply-demand planning and controlling device 500 in the charging plan planning device 250. The supply-demand planning and controlling device 500 is configured with a power supply amount predicting DB 276, a power demand amount predicting DB 277, a storage battery DB 278, a plan and control calculating section 374, and a storage battery charge-discharge plan DB 279. The power supply amount predicting DB 276 has a same content as data 359 described regarding FIG. 10, and data 376 stored therein is also the same as the data 359.

Further, the power demand amount predicting DB 277 is also the same as the demand amount predicting plan DB 365 shown in FIG. 9, and that data format 377 is also the same as the data 369. Further, the storage battery DB 278 is accumulated with data regarding the storage battery in a format shown in data 378. The content is data configured from an arbitrary combination of any of an initial SOC when starting charge of a storage battery, a target SOC, a charging target time, degradation information such as an index calculated with the storage battery analysis system 100, a capacity of an object storage battery, a charging type of the storage battery. In this case, at least the degradation information has to be included.

The plan and control calculating section 374 uses each of the data in the data bases 276-278 described above to generate a storage battery charging-discharging plan in each time, or a control period, and stores the result in the storage battery charge-discharge plan DB 279. As a technique used to generate the storage battery charge-discharge plan, for example, techniques represented with a well-known Lagrange's undetermined coefficient method, a regression analysis method, a linear computation method, a neural network, a tab search, and a genetic algorithm. Regarding an example implementing the plan and control calculating section 374, for example, a detailed technique is disclosed in Japanese Patent Application Laid-open Publication No. 2000-209707 as an example using a genetic algorithm. Note that, the parameters in the storage battery DB 278 can be used as constraints in respect to the optimization calculating technique. In the calculation here, the degradation information is stored in a form of a ratio that cannot be used due to degradation in respect to the overall capacity, and at the time of creating the plan is multiplied with a value of “capacity” in the data format 378, and the plan is created with the decreased capacity value of the storage battery. In this way, the plan planning calculation in view of the degradation of the storage battery becomes possible. The calculation result is in a format illustrated in the data 379, and stores the charging amount (discharging amount) in each time of each storage battery. Regarding the charge amount of every storage battery, for example, the charge-discharge plan planning device 250 (or the storage battery analysis system 100) calculates a surplus/shortage amount of power supply amount generated in the power system as a charge amount to be charged in the storage battery, based on a predicted value of the power demand amount and the power supply amount, and distributes the calculated charge amount as a charge planned amount of each storage battery, according to the capacity of each storage battery (based on the data 378). As a technique for distribution, there can be assumed a technique to sequentially identify from the storage battery according to the descending order of a capacity and distribute the charge amount for just the capacity amount.

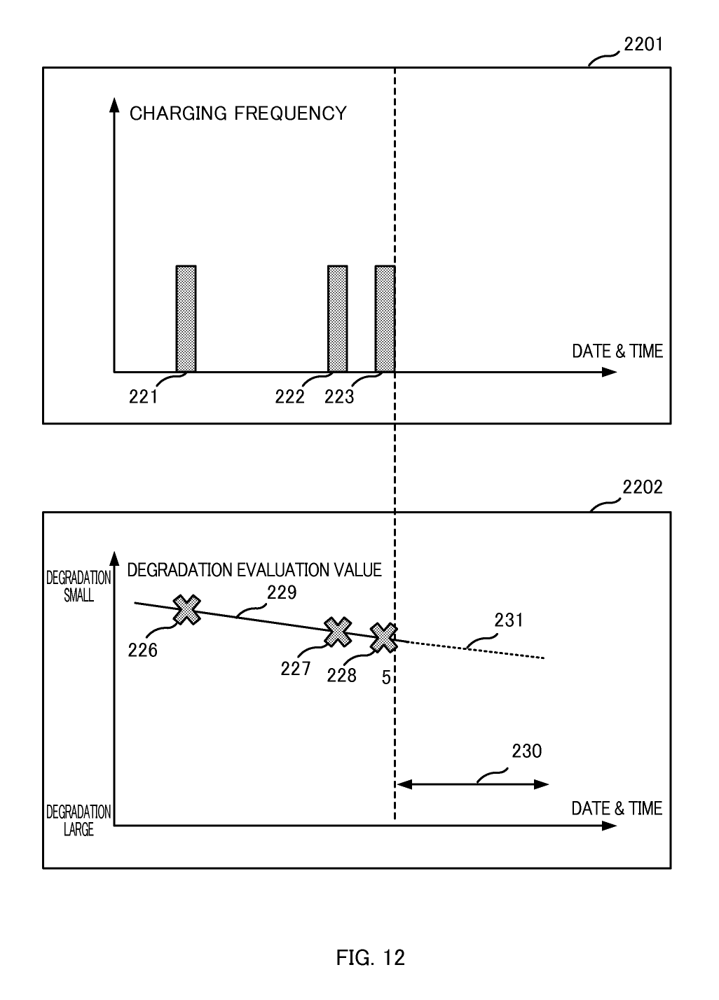

What is to be noted here is that the information relating to degradation cannot be acquired in a predetermined period. Thus, as shown in an upper graph 2201 in FIG. 12, in the case that there is no charging after a certain period 223, when performing a first charging plan after that, it is necessary to accurately predict degradation of the storage battery after the period 223, and to reflect it in the plan result. As such a method, as shown in a lower graph 2202 in FIG. 12, a tendency of a time series variation of a past index is calculated by a statistics analysis such as regression analysis, and degradation along such a tendency is predicted (for example, in the case that a tendency line 231 is drawn, charging plan and control during a period 230 uses an index value on the tendency line 231.).

By performing the plan creation described above, it becomes possible to plan the charge-discharge plan of the storage battery that takes into consideration degradation of the storage battery to be a subject of charge-discharging. Thus, it becomes possible to plan a charging plan to prevent influence of power quality deterioration in a regional system where the storage battery is installed.

The embodiments have been explained above, but the above embodiments are to facilitate understanding of this invention and do not limit this invention in any way. This invention can be altered or improved without departing from its scope, and this invention includes its equivalents.

According to such an embodiment mode, the degradation state of the storage battery can be accurately estimated.

With the description of this specification, at least the following matters are made clear. Namely, with the storage battery analysis system, the system may include a communication device that communicates with a charge-discharge device that charges and discharges a storage battery, an arithmetic device may executes a process to communicate with the charge-discharge device via the communication device, acquire time series variation data of a voltage value and a current value during a charging period of the storage battery, and store the acquired data in a storage device.

Further, with the storage battery analysis system, wherein

the storage device may store the time series variation data of the voltage value and the current value in each period of an initial usage period and an analysis period, in the case that a charging method in which a constant-voltage charging is performed after a constant-current charging,

the arithmetic device may read out from the storage device the data relating to the voltage value and the current value during the constant-voltage charging period, of the time series variation data of the voltage value and the current value in each period of the initial usage period and the analysis period, in the case that the charging method in which the constant-voltage charging is performed after the constant-current charging, calculate a charging power amount at the time of the constant-voltage charging in each period based on the read data, calculate a difference or a ratio between the initial usage period and the analysis period regarding the calculated charging power amount during the constant-voltage charging period, and store the difference or the ratio as an index showing a degradation state of the storage battery.

Further, with the storage battery analysis system, wherein

the storage device may store the time series variation data of the voltage value and the current value in each period of the initial usage period and the analysis period, in the case that a charging method in which a constant-voltage charging is performed after a constant-current charging,

the arithmetic device may read out from the storage device the data relating to the voltage value and the current value during a constant-voltage charging period, of the time series variation data of the voltage value and the current value in each period of the initial usage period and the analysis period, in the case that the charging method in which the constant-voltage charging is performed after the constant-current charging, calculate a time required for the constant-voltage charging in each period based on the read data, calculates a difference or a ratio between the initial usage period and the analysis period regarding the calculated time, and store in the storage device the difference or the ratio as an index showing a degradation state of the storage battery.

Further, with the storage battery analysis system, wherein

the storage device may store the time series variation data of the voltage value and the current value in each period of the initial usage period and the analysis period, in the case that a charging method in which only a constant-current charging is performed,

the arithmetic device may read out from the storage device the time series variation data of the voltage value and the current value in each period of the initial usage period and the analysis period, in the case that the charging method in which only the constant-current charging is performed, calculate a time taken for the constant-current charging in each period based on the read data, calculates a difference or a ratio between the initial usage period and the analysis period regarding the calculated time, and store in the storage device the difference or the ratio as an index showing a degradation state of the storage battery.

Further, with the storage battery analysis system, wherein

the arithmetic device may store the time series variation data of the voltage value and the current value in each period of the initial usage period and the analysis period, in the case that the charging method in which a constant-voltage charging is performed after the constant-current charging,

the arithmetic device may read out from the storage device the data regarding the voltage value and the current value in a constant-current charging period, of the time series variation data of the voltage value and the current value in each period of the initial usage period and the analysis period, in the case that the charging method in which the constant-voltage charging is performed after the constant-current charging, calculate a time taken for the constant-current charging in each period based on the read data, calculate a difference or a ratio between the initial usage period and the analysis period regarding the calculated time, and store in the storage device the difference or the ratio as an index showing a degradation state of the storage battery.

The storage battery analysis system, wherein

the arithmetic device may store the time series variation data of the voltage value and the current value in each period of the initial usage period and the analysis period, in the case that the charging method in which a constant-voltage charging after the constant-current charging is executed,

the arithmetic device may read out from the storage device the data regarding the voltage value during the constant-current charging period, of the time series variation data of the voltage value and the current value in each period of the initial usage period and the analysis period, in the case that the charging method in which the constant-voltage charging is performed after the constant-current charging, based on the read data, calculate a time taken for the voltage value at a charge start time to reach 50% of the voltage value during the constant-voltage charging period in each period, calculate the difference or the ratio between the initial usage period and the analysis period for the calculated time, and stores in the storage device the difference or the ratio as an index showing a degradation state of the storage battery.

The storage battery analysis system, wherein

the arithmetic device may execute
a process to read out from the storage device the time series variation data of the voltage value and the current value during the charging period measured in the initial usage period and the time series variation data of the voltage value and the current value during the charging period measured in one or a plurality of the analysis periods, compare the respective time series variation data as read, identify a difference in the time series variation between the initial usage period and each analysis period, and make the difference an index showing a degradation state of the storage battery in each analysis period,
a process to calculate with a predetermined statistics analysis a time series variation tendency of the index of each analysis period, based on the calculated time series variation tendency, calculates the index regarding a predetermined period of a period in which charging is not performed after the analysis period, and stores it in the storage device.

The storage battery analysis system, wherein

the arithmetic device may execute
a process to store in the storage device the index for each storage battery, and
a process, based on a predicted value of a power demand amount and a power supply amount in an electric power system connected with the storage battery, to calculate a surplus/shortage amount of the power supply amount generated in the electric power system as a charge amount to be charged to the storage battery, distribute the calculated charge amount as a charge planned amount of each storage battery, according to a storage capacity based on an index of each storage battery, and store in the storage device the charge planned amount of each storage battery.

### REFERENCE SIGNS LIST

11, 21 Storage device
12, 22 Program
13, 23 Memory
14, 24 Arithmetic device
15, 25 Input device
16, 26 Output device
17, 27 Communication IF (communication device)
18, 28 Communication bus
100 Storage battery analysis system
110 Storage battery class determining section
111 Data comparing section
112 Data acquiring section
113 Degradation determining section
115 Storage battery management DB
116 Storage battery model DB
180 Communication network
181 Pole transformer
182 EVSE (Charging device)
183 Electric car (Storage battery)
185 Communication line
186 Communication line
187 Wiring line
188 Charging cable
201 Tendency of voltage
202, 211, 213 Tendency of current
250 Charge-discharge plan planning device
255 History DB
256 Demand history DB
257 Demand external factor DB
258 Demand correction DB
259 Demand amount predicting plan DB
266 Demand amount plan DB
267 Facility operating plan
268 Facility characteristic DB
269 Supply amount predicting plan DB
276 Power supply amount predicting DB
277 Power demand amount predicting DB
278 Storage battery DB
279 Storage battery charge-discharge plan DB
300 Power supply amount predicting device
354 Supply amount predicting section
364 Demand predicting section
374 Plan and control calculating section
400 Power demand amount predicting device
500 Supply-demand planning and controlling device
600 Charging management device
700 Charging request management device

1. A storage battery analysis system comprising:
a storage device storing data of time series variation of a voltage value and a current value during a charging period of a storage battery measured in an initial usage period within a certain period from start of usage, and data of time series variation of the voltage value and the current value during the charging period of the storage battery measured in an analysis period after the certain period has passed; and
an arithmetic device that executes a process to read out the time series variation data of the voltage value and the current value during the charging period of the battery measured in the initial usage period and the time series variation data of the voltage value and the current value during the charging period of the battery measured in the analysis period, compare the respective time series variation data as read, identify a difference in the time series variation between the initial usage period and the analysis period, and store in the storage device the difference as an index indicating a degradation state of the storage battery.

2. The storage battery analysis system according to claim 1, wherein
the system comprises a communication device that communicates with a charge-discharge device that charges and discharges a storage battery, and
the arithmetic device executes a process to communicate with the charge-discharge device via the communication device, acquire the time series variation data of the voltage value and the current value during the charging period of the storage battery, and store the acquired data in the storage device.

3. The storage battery analysis system according to claim 1, wherein
the storage device stores the time series variation data of the voltage value and the current value in each period of the initial usage period and the analysis period, in the case that a charging method in which a constant-voltage charging is performed after a constant-current charging, and
the arithmetic device reads out from the storage device the data relating to the voltage value and the current value during the constant-voltage charging period, of the time series variation data of the voltage value and the current value in each period of the initial usage period and the analysis period, in the case that the charging method in which the constant-voltage charging is performed after the constant-current charging, calculates a charging power amount at the time of the constant-voltage charging in each period based on the read data, calculates a difference or a ratio between the initial usage period and the analysis period regarding the calculated charging power amount during the constant-voltage charging period, and stores the difference or the ratio as an index showing a degradation state of the storage battery.

4. The storage battery analysis system according to claim 1, wherein
the storage device stores the time series variation data of the voltage value and the current value in each period of the initial usage period and the analysis period, in the case that a charging method in which a constant-voltage charging is performed after a constant-current charging, and
the arithmetic device reads out from the storage device the data relating to the voltage value and the current value during the constant-voltage charging period, of the time series variation data of the voltage value and the current value in each period of the initial usage period and the analysis period, in the case that the charging method in which the constant-voltage charging is performed after the constant-current charging, calculates a time required for the constant-voltage charging in each period based on the read data, calculates a difference or a ratio between the initial usage period and the analysis period regarding the calculated time, and stores in the storage device the difference or the ratio as an index showing a degradation state of the storage battery.

5. The storage battery analysis system according to claim 1, wherein
the storage device stores the time series variation data of the voltage value and the current value in each period of the initial usage period and the analysis period, in the case that a charging method in which only a constant-current charging is performed, and
the arithmetic device reads out from the storage device the time series variation data of the voltage value and the current value in each period of the initial usage period and the analysis period, in the case that the charging method in which only the constant-current charging is performed, calculates a time taken for the constant-current charging in each period based on the read data, calculates a difference or a ratio between the initial usage period and the analysis period regarding the calculated time, and stores in the storage device the difference or the ratio as an index showing a degradation state of the storage battery.

6. The storage battery analysis system according to claim 1, wherein
the arithmetic device stores the time series variation data of the voltage value and the current value in each period of the initial usage period and the analysis period, in the case that the charging method in which the constant-voltage charging is performed after the constant-current charging,
the arithmetic device reads out from the storage device the data regarding the voltage value and the current value in the constant-current charging period, of the time series variation data of the voltage value and the current value in each period of the initial usage period and the analysis period, in the case that the charging method in which the constant-voltage charging is performed after the constant-current charging, calculates a time taken for the constant-current charging in each period based on the read data, calculates a difference or a ratio between the initial usage period and the analysis period regarding the calculated time, and stores in the storage device the difference or the ratio as an index showing a degradation state of the storage battery.

7. The storage battery analysis system according to claim 1, wherein
the arithmetic device stores the time series variation data of the voltage value and the current value in each period of the initial usage period and the analysis period, in the case that the charging method in which the constant-voltage charging is performed after the constant-current charging,
the arithmetic device reads out from the storage device the data regarding the voltage value during the constant-current charging period, of the time series variation data of the voltage value and the current value in each period of the initial usage period and the analysis period, in the case that the charging method in which the constant-voltage charging is performed after the constant-current charging, based on the read data, calculates a time taken for the voltage value at a charge start time to reach 50% of the voltage value during the constant-voltage charging period in each period, calculates the difference or the ratio between the initial usage period and the analysis period for the calculated time, and stores in the storage device the difference or the ratio as an index showing a degradation state of the storage battery.

8. The storage battery analysis system according to claim 1, wherein
the arithmetic device executes
a process to read out from the storage device the time series variation data of the voltage value and the current value during the charging period measured in the initial usage period and the time series variation data of the voltage value and the current value during the charging period measured in one or a plurality of the analysis periods, compare the respective time series variation data as read, identify a difference in the time series variation between the initial usage period and each analysis period, and make the difference an index showing a degradation state of the storage battery in each analysis period,
a process to calculate with a predetermined statistics analysis a time series variation tendency of the index of each analysis period, based on the calculated time series variation tendency, calculates the index regarding a predetermined period of a period in which charging is not performed after the analysis period, and stores it in the storage device.

9. The storage battery analysis system according to claim 1, wherein
the arithmetic device executes
a process to store in the storage device the index for each storage battery, and
a process, based on a predicted value of a power demand amount and a power supply amount in an electric power system connected with the storage battery, to calculate a surplus/shortage amount of the power supply amount generated in the electric power system as a charge amount to be charged to the storage battery, distribute the calculated charge amount as a charge planned amount of each storage battery, according to a storage capacity based on an index of each storage battery, and store in the storage device the charge planned amount of each storage battery.

10. A storage battery analysis method, the method comprising
causing a computer having a storage device storing data of time series variation of a voltage value and a current value during a charging period of a storage battery measured in an initial usage period within a certain period from start of usage, and data of time series variation of the voltage value and the current value during the charging period of the storage battery measured in an analysis period after the certain period has passed,
to execute a process to read out from the storage device the time series variation data of the voltage value and the current value during the charging period of the battery measured in the initial usage period and the time series variation data of the voltage value and the current value during the charging period of the battery measured in the analysis period, compare the respective time series variation data as read, identify a difference in the time series variation between the initial usage period and the analysis period, and store in the storage device the difference as an index indicating a degradation state of the storage battery.

11. A storage battery analysis program, the program comprising
causing a computer having a storage device storing data of time series variation of a voltage value and a current value during a charging period of a storage battery measured in an initial usage period within a certain period from start of usage, and data of time series variation of the voltage value and the current value during the charging period of the storage battery measured in an analysis period after the certain period has passed,
to execute a process to read out from the storage device the time series variation data of the voltage value and the current value during the charging period of the battery measured in the initial usage period and the time series variation data of the voltage value and the current value during the charging period of the battery measured in the analysis period, compare the respective time series variation data as read, identify a difference in the time series variation between the initial usage period and the analysis period, and store in the storage device the difference as an index indicating a degradation state of the storage battery.
